(19) United States
(12) Patent Application Publication
(10) Pub. No.: US 2025/0300051 A1
(43) Pub. Date: Sep. 25, 2025

(54) INTERCONNECT STRUCTURE WITH REENTRANT VIA BOTTOM SIDEWALL

(71) Applicant: Intel Corporation, Santa Clara, CA (US)

(72) Inventors: Shafaat Ahmed, Albuquerque, NM (US); Man Fai Ng, Albuquerque, NM (US); Tanjim Ahmed, Albuquerque, NM (US); Koffi Godwin, Rio Rancho, NM (US); Muhymin Islam, Rio Rancho, NM (US); Darren Denardis, Albuquerque, NM (US)

(73) Assignee: Intel Corporation, Santa Clara, CA (US)

(21) Appl. No.: 18/615,201

(22) Filed: Mar. 25, 2024

(51) Int. Cl. H01L 23/498; H01L 21/768; H01L 23/00; H01L 25/065

(52) U.S. Cl. CPC H01L 23/49822; H01L 21/76877; H01L 23/49816; H01L 24/05; H01L 24/13; H01L 25/0655; H01L 2224/05005; H01L 2224/05025; H01L 2224/13009; H01L 2224/13026; H01L 2924/01029; H01L 2924/1431; H01L 2924/1434; H01L 2924/15311

(57) ABSTRACT

Interconnect structures having reentrant sidewalls at via bottoms. A via may be over and coupled to a metallization layer, extending through upper and lower dielectric layers over the metallization layer, and having a reentrant sidewall in the thinner, lower dielectric layer. The via may have a narrower width level with an interface of the upper and lower dielectric layers. The via may couple to a second metallization layer over the via, and the via may have a reentrant sidewall adjacent the upper metallization layer. The via structure may be in a bridge die, interposer, IC die, etc.

### BACKGROUND

Innovations are needed to maintain and improve integrated circuit (IC) device reliabilities, especially as devices are subject to ever-increasing current densities due to device dimensions scaling down while powers increase. For example, elevated current densities may result in electromigration issues and consequent early failures in IC interconnects, including unpredictably early failures. Unpredictable (i.e., unreliable) failures may increase necessary design margins and so severely limit allowable total or average current densities.

New techniques, structures, and materials are needed to improve reliability performance of interconnects in IC systems.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views a device having a conductive via with a reentrant bottom sidewall in a lower dielectric layer, in accordance with some embodiments;

FIGS. 2A, 2B, 2C, 2D, and 2E illustrate cross-sectional profile views of a device having a reentrant-profile via coupling between metal lines in metallization layers, in accordance with some embodiments;

FIG. 3 is a plot of cumulative distribution functions corresponding to via bottom widths for both improved and conventional via structures, in accordance with some embodiments;

FIG. 4 is a plot of reliability testing time-to-failure results in relation to the dielectric angle at the via bottom, in accordance with some embodiments;

FIGS. 5A, 5B, 5C, and 5D illustrate cross-sectional profile views of integrated circuit (IC) devices including IC dies coupled by a substrate, in accordance with some embodiments;

FIG. 6 illustrates a cross-sectional view of an IC system having improved vias in front- and back-side interconnect sections, over and under transistor structures in a device layer, in accordance with some embodiments;

FIG. 7 is a flow chart of methods for forming a conductive via with a reentrant bottom sidewall in one or more dielectric layers, in accordance with some embodiments;

FIGS. 8A, 8B, 8C, 8D, 8E, and 8F illustrate cross-sectional profile views of a device having a conductive via with a reentrant bottom sidewall, at various stages of manufacture, in accordance with some embodiments;

FIG. 9 illustrates a diagram of an example data server machine employing an IC device having an interconnect via with reentrant bottom sidewalls, in accordance with some embodiments; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the reliability performance of interconnect structures in integrated circuit (IC) devices, e.g., having one or more IC dies. The more-reliable devices may have improved interconnects, e.g., between metallization lines and vias, and fewer early or otherwise unpredictable failures, such as opens, shorts, etc., caused by electromigration in an interconnect structure.

Electromigration is a key reliability factor, and IC interconnect technologies must be robust against, and minimize failures caused by, electromigration effects. Besides the material properties of interconnect(s), the conductor dimensions and shape, joints or interfaces between conductor constituents (including metal grain boundaries), material deposition or other treatment methods, characteristics of dielectric or other adjacent materials, etc., may also affect interconnect electromigration durability.

For example, electromigration failures (such as voids or other opens at via bottoms) can be prevented, or at least minimized, by rounding off an acute or right angle of the direction of current flow to a larger, more-gradual obtuse angle at the joint between a metal via and line below the via. The improved via structure, having a reentrant profile with a flared bottom at the joining to the line, corresponds to a reduced current density (relative to a conventional via bottom) at the corner and joint. The reentrant profile, e.g., rather than a bulging profile, refers to the via sidewall or sidewall angle pointing inward from an end of the via toward an axis of the via at a neck or waist of the via. The flared bottom refers to the widening of the sidewall away from the axis and towards the lower end of the via, away from the neck. The angle at the via bottom, and the process for making the improved angle, may correspond to a more-controlled formation of the via and joint between the via and line below and a consequently tighter critical dimension (CD) distribution, e.g., of the via width. The more-consistent CD may better ensure sufficient area on lower metal line for attachment of a via bottom surface. While any flaring or necking may result in a narrowed minimum width for a given maximum width, the flared via profile guarantees that a tapered neck of the via is up the via, away from a joint or interface between the via and a metal line below the via. To ensure a sufficiently wide via, an optimal reentrant or flaring angle in dielectric may be only minimally greater than 90°, for example, between 90° and 92°.

The improved via and interconnect structure may be deployed in any of various contexts: in IC dies, e.g., over and/or under a device layer; in a multichip interconnect bridge, e.g., coupling dies in an IC package; in an interposer, e.g., for interfacing between a package substrate and one or more IC dies; etc. The improved via structure and process may be employed in all of these contexts or only where needed, for example, in circuit locations of highest current density.

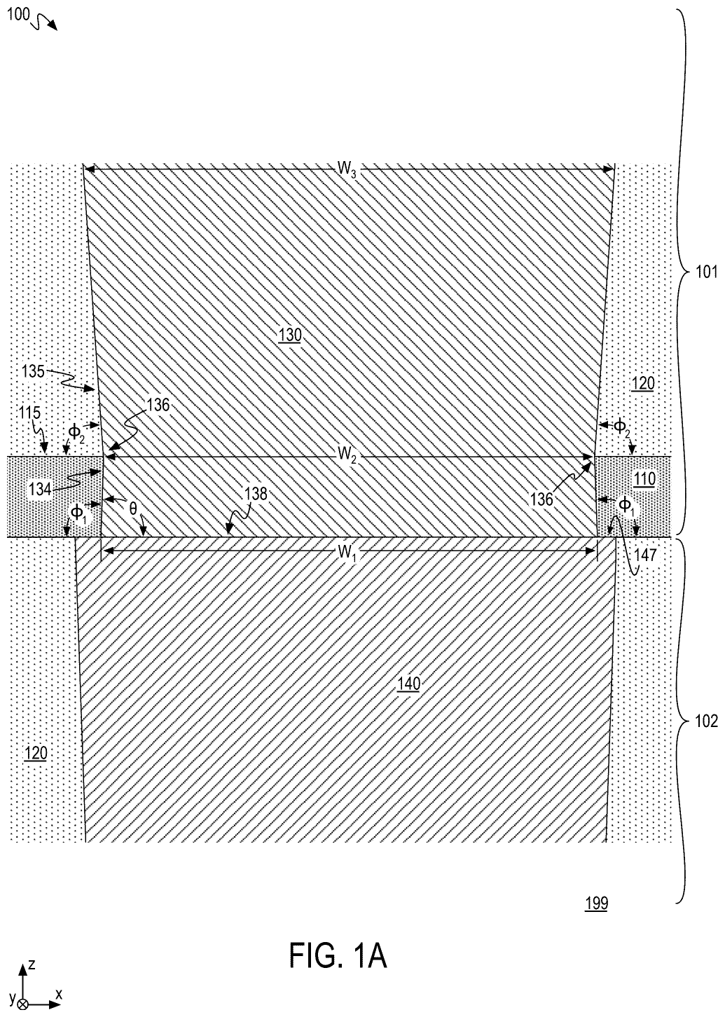

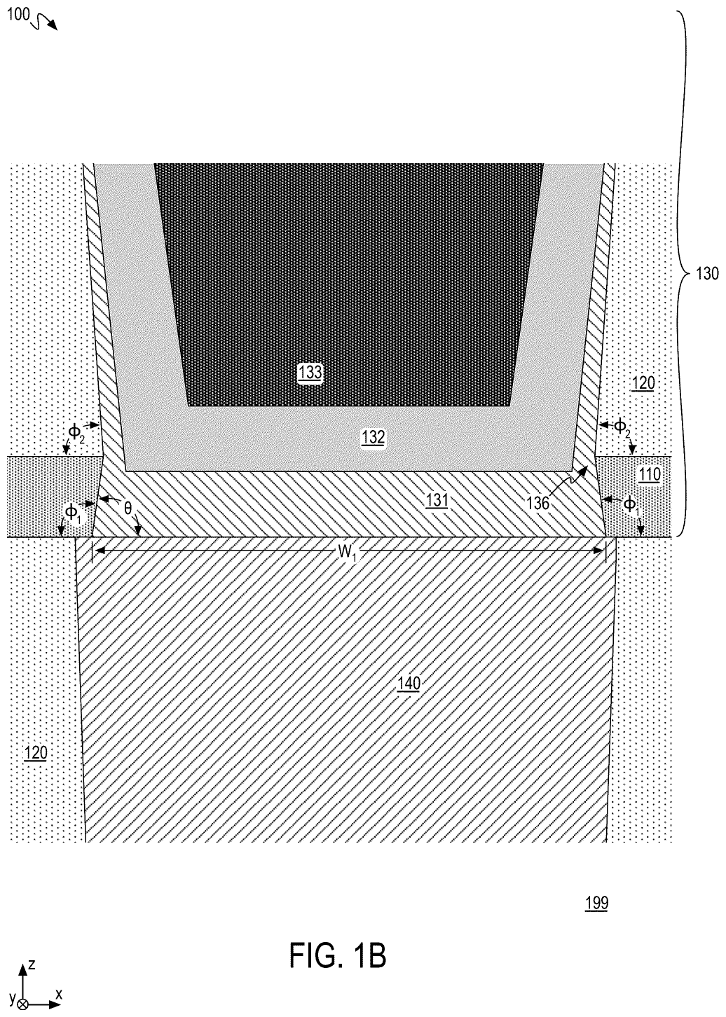

FIGS. 1A and 1B illustrate cross-sectional profile views of a device 100 having a conductive via 130 with a reentrant bottom sidewall 134 in lower dielectric layer 110, in accordance with some embodiments. FIG. 1A shows via 130 extending vertically through dielectric layers 110, 120 in or on substrate 199 and coupling metal line 140 in interconnect or metallization layer 102. Via 130 flares outward from width W₂ at a waist or neck 136 to a greater width W₁ at a lower interface or surface 138. A width W₃ is over or above neck 136, and width W₃ is greater than width W₂ at neck 136. Via 130 tapers inward towards neck 136 with reentrant sidewalls 134, 135 above and below neck 136.

Another line 140 may be above (e.g., in interconnect or metallization layer 101) and similarly couple with via 130. Via 130 may be vertically between and couple metal lines 140 extending horizontally through dielectric layers 120 in metallization layers 101, 102. Metallization layers 101, 102 may be part of an interconnect structure in substrate 199 that includes multiple interconnect or metallization layers 101, 102, etc., with each interconnect or metallization layer including one or more metal lines 140 in and extending through dielectric (e.g., layer 120). Each interconnect layer (e.g., layer 101) may include dielectric layers (e.g., layers 110, 120) over metal lines 140 in the interconnect layer below (e.g., layer 102). For example, dielectric layer 110 is in metallization layer 101 and over metallization layer 102 (and line 140 in metallization layer 102). Dielectric layer 120 is also in metallization layer 101 and is over dielectric layer 110. Via 130 may be characterized as in or part of metallization layer 101 or between metallization layers 101, 102.

FIG. 1A illustrates a dielectric angle ϕ₁ in dielectric layer 110 between metallization layer 102 and sidewall 134 of via 130. In the exemplary embodiment of FIG. 1A, angle ϕ₁ measures greater than 90° between sidewall 134 and an upper surface 147 of metal line 140 in layer 102. Angle ϕ₁ measures greater than 90° between the layer 102 and sidewall 134. For example, angle ϕ₁ measures greater than 90° between sidewall 134 and dielectric layer 120, e.g., between sidewall 134 and an interface or surface 147 between dielectric layers 110, 120 (of interconnect layers 101, 102, respectively). The upper surface 147 of metal line 140 is substantially coplanar with the bottom surface of via 130 and the interfacing surfaces of and between dielectric layers 110, 120. Dielectric angle ϕ₁ in dielectric layer 110 measuring greater than 90° corresponds to sidewall 134 pointing inward toward an axis of via 130 at neck 136, and to metal angle θ in via 130 measuring less than 90°.

An optimal angle ϕ₁ may be just greater than 90° to minimize narrowing of via 130. Excessive narrowing of via 130 might adversely increase current density through via 130 and consequently exacerbate electromigration effects. For example, an optimal angle ϕ₁ may be greater than, but within two degrees of, 90°. In some embodiments, angle ϕ₁ is 92° or less. In some such embodiments, angle ϕ₁ is 91° or less. An angle ϕ₁ greater than 90° ensures that, rather than a sharp corner of 90° or less, current through via 130 and line 140 may have a more-gradual change of direction, which may aid in minimizing electromigration effects. An angle ϕ₁ greater than 90° also ensures that the narrowest width of via 130 is above the interface with metal line 140. An angle ϕ₁ close to 90° ensures that the width of via 130 is not overly narrow. For example, an overly large or small angle ϕ₁ (e.g., of 95° or more, or 85° or less) corresponds to an overly slanted sidewall 134, excessive narrowing of via 130, and a too-small minimum width of via 130 (e.g., for a given maximum width).

Neck 136 refers to the portion of via 130 having a narrowest width W₂ of via 130. Neck 136 may be a cross-section of via 130, e.g., in a horizontal plane (orthogonal to a vertical axis of via 130 and at a constant height up the axis), or that height of via 130 having a narrowest width W₂ of via 130. Neck 136 may be at or level with an interface of or between dielectric layers 110, 120 in metallization layer 101. With via sidewall 134 pointing inward and upward away from metal line 140, via 130 has width W₂ at neck 136 (at a top of layer 110, between dielectric layers 110, 120, above surface 147) less than width W₁ at a lower interface or surface 138. The interface between via 130 and line 140 and metallization layer 102 is at lower surface 138 of via 130. Via 130 has a width W₃ (above neck 136 and the interface between dielectric layers 110, 120) wider or greater than width W₂.

Dielectric angle ϕ₂ is in dielectric layer 120 of metallization layer 101. Dielectric angle ϕ₂ measures less than 90° between dielectric layer 110 (e.g., at an interface 115 between layers 110, 120) and a sidewall 135 of via 130 in metallization layer 101. A dielectric angle ϕ₂ of less than 90° corresponds to a taper of via 130 from a larger width W₃ above neck 136 to a narrowest width W₂ at neck 136. As with angle ϕ₁, an angle ϕ₂ close to 90° ensures that the width of via 130 is not overly narrow. In some embodiments, angle ϕ₂ is 88° or more. In some such embodiments, angle ϕ₂ is 89° or more. In some embodiments, angle ϕ₂ is within 4° of angle ϕ₁, (e.g., with an angle ϕ₁ of 92° or less and an angle ϕ₂ of 88° or more), which may correspond to a maximal minimum width W₂. A smaller angle ϕ₂ (e.g., of 85° or less) corresponds to a more-slanted sidewall 135, more narrowing of via 130, and a smaller minimum width of via 130 (e.g., for a given maximum width). However, an angle ϕ₂ more closely approaching 90° may require more processing resources (e.g., time), and a balance may be struck between cost and an angle ϕ₂ approaching vertical. In some embodiments, angle ϕ₁ is more than 5° greater than angle ϕ₂ (e.g., with an angle ϕ₁ of 92° or less and more than 90°, and with an angle ϕ₂ of 87° or less).

Via 130 is a conductive structure that couples other conductive structures, such as metal lines 140, in metallization layers 101, 102. Via 130 and lines 140 may include any suitably conductive material(s). For example, via 130 and lines 140 may include one or more metallic materials. In some embodiments, via 130 and lines 140 include copper. In some embodiments, via 130 and lines 140 include nickel. Via 130 and lines 140 may include other materials, such as ruthenium, cobalt, molybdenum, etc. Via 130 may have any suitable shape. In many embodiments, via 130 is symmetric about a vertical axis, e.g., in one or both of the x-z and y-z planes. A cross-section of via 130 in a horizontal (e.g., x-y) plane may have a circular, rectangular, or other shape. Such a cross-section, for example, if substantially rectangular, may have rounded corners.

Dielectric layers 110, 120 may perform similar functions and include similar materials. For example, layers 110, 120 may both include electrically insulating materials that mechanically support and electrically isolate various electrically conducting structures, such as lines 140 and vias 130. In some embodiments, dielectric layers 120 include a low-permittivity (“low-K”) dielectric material. In some embodiments, dielectric layers 120 include oxygen, e.g., in an oxide. In some such embodiments, dielectric layers 120 include silicon, e.g., in an oxide of silicon (such as silicon dioxide, SiO₂). Dielectric layers 120 may provide most of the electrical isolation in (and most of the height of) metallization layers, e.g., layers 101, 102. In many embodiments, dielectric layer 110 includes a dielectric material having an etch selectivity with layers 120.

Dielectric layer 110 may provide an etch-stop layer between the bulk of dielectric layers 120 in interconnect layers 101, 102. In many embodiments, a dielectric material of lower dielectric layer 110 advantageously enables an etch chemistry at least somewhat selective to metallization layers 101, 102 (e.g., line 140). An etch chemistry that selectively removes dielectric material of lower dielectric layer 110 and retains that of, e.g., metallization line 140 prevents an undercut of the metallization layer 102 under dielectric layer 110. Etching under lower dielectric layer 110 may form voids that subsequent deposition (e.g., of a metal liner as part of via 130 and layer 101) will not fill in. Such voids may then act as a notch for crack initiation and propagation and lead to early failures, e.g., during reliability testing or in the field. In some embodiments, dielectric layers 110 include nitrogen, e.g., in a nitride. In some such embodiments, dielectric layers 110 include silicon, e.g., in a nitride of silicon (such as silicon nitride, SiₓN_{y}). In some embodiments, dielectric layers 110 include carbon. In some such embodiments, dielectric layers 110 include silicon, nitrogen, and carbon (e.g., in carbon-doped silicon nitride, SiₓC_{y}N_{z}), which may advantageously enable an etch chemistry selective to metallization layers 101, 102 (e.g., line 140).

Metallization layers 101, 102 and dielectric layers 110, 120 are on substrate 199 of device 100. Substrate 199 may be any suitable substrate. Substrate 199 may include any suitable material or materials. Any suitable semiconductor or other material may be used. Substrate 199 may be any suitable substrate, such as a wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, substrate 199 includes crystalline silicon and subsequent components are also silicon. Substrate 199 may be a silicon-on-insulator (SOI) substrate. Substrate 199 may also include metals, dielectrics, dopants, and other materials commonly found in IC substrates.

FIG. 1B shows a similar embodiment of device 100, but with via 130 having multiple layers or portions of different conductive materials. In some embodiments, via 130 includes a layer 131, e.g., a barrier layer 131, on metal line 140 and dielectric layers 110, 120. Layer 131 may provide an interface between via 130 (such as internal layer 132 and portion 133) and line 140 and layers 110, 120. For example, a barrier layer 131 may prevent diffusion of the material(s) of layer 132 and/or portion 133 into layers 110, 120. In some embodiments, layer 131 is a seed layer 131 that facilitates further formation, deposition, etc., of other conductive materials (e.g., of layer 132 and portion 133) of via 130.

In some embodiments, via 130 includes a layer 132, e.g., a seed layer 132, on layer 131. Layer 132 may provide an interface between layer 131 and portion 133. For example, a seed layer 132 may facilitate further formation, deposition, etc., of other conductive materials (e.g., of portion 133) of via 130. In some embodiments, a single layer 131 or 132 is between portion 133 and metal line 140 and dielectric layers 110, 120. In some embodiments, via 130 includes portion 133, which may be a bulk portion 133 providing the majority of the volume and mass of via 130. In some such embodiments, portion 133 is formed or deposited over seed layer(s) 131 or 132. Portion 133 may be formed or deposited by any suitable means.

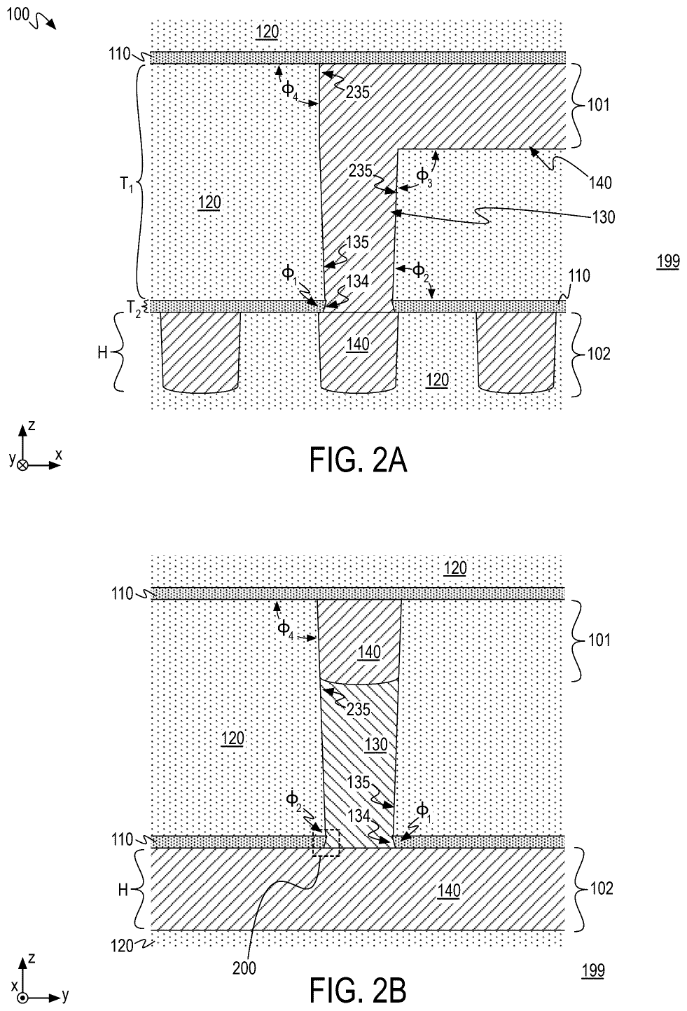

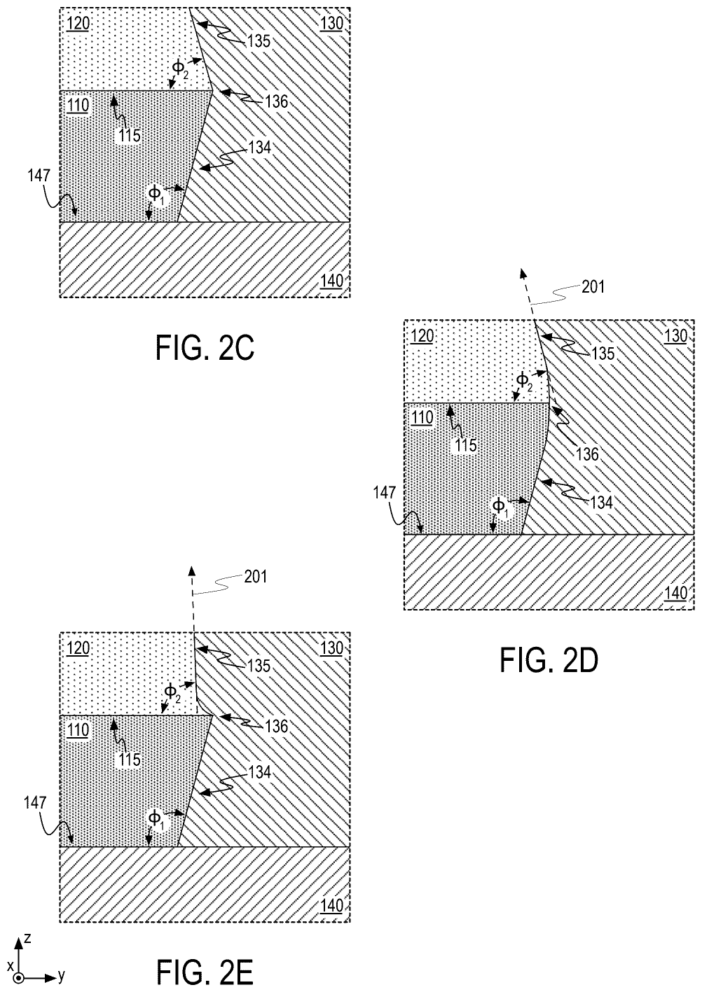

FIGS. 2A, 2B, 2C, 2D, and 2E illustrate cross-sectional profile views of device 100 having a reentrant-profile via 130 coupling between metal lines 140 in metallization layers 101, 102, in accordance with some embodiments. FIGS. 2A, 2B show cross-sectional profiles of lines 140 in adjacent metallization layers 101, 102 and extending in perpendicular directions, for example, as in a Manhattan routing scheme. Lines 140 in adjacent layers 101, 102, etc., may be oriented otherwise, as is suitable for a particular context. The x-z viewing plane of FIG. 2A illustrates a longitudinal cross-section of line 140 in layer 101 and transverse cross-sections of lines 140 in layer 102. The y-z viewing plane of FIG. 2B illustrates a transverse cross-section of line 140 in layer 101 and a longitudinal cross-section of line 140 in layer 102. Though shown in FIG. 2A as an integrated structure, in some embodiments, via 130 and upper line 140 are joined, but distinct, vertical and horizontal structures. FIG. 2B shows a view 200, which is expanded in FIGS. 2C-2E, e.g., to show details of the interfaces between via 130, line 140, and layers 110, 120.

FIGS. 2A, 2B show via 130 similar to FIGS. 1A, 1B and with additional context in substrate 199. Dielectric layer 110 is over metallization layer 102 and metal lines 140 of layer 102. Dielectric layer 120 in metallization layer 101 is over dielectric layer 110. Via 130 extends through dielectric layers 110, 120. Via 130 is between and coupled with metallization layers 101, 102 (e.g., with lines 140 of metallization layers 101, 102). Dielectric angle ϕ₁ measures greater than 90° between sidewall 134 and metal line 140 in layer 102. Dielectric angle ϕ₂ in dielectric layer 120 of metallization layer 101 measures less than 90° between dielectric layer 110 and sidewall 135 of via 130.

Dielectric layer 120 has a thickness T₁ greater than a thickness T₂ of dielectric layer 110. Layer 110 may be an etch-stop layer. In some embodiments, layer 110 has a thickness T₂ of less than 200 nm. Layer 110 may be only as thick as necessary to facilitate a foot of via 130, e.g., with reentrant lower sidewall(s) 134. In some embodiments, layer 110 has a thickness T₂ of less than 100 nm. Similar dielectric layers 110, 120 (e.g., with similar thicknesses T₁, T₂) are above those shown in interconnect layers 101, 102. An additional dielectric layer 110 is over metallization layer 101 and metal line 140 of layer 101. An additional dielectric layer 120 is over the dielectric layer 110 over metallization layer 101.

In some embodiments, dielectric layer 120 is of a low-K dielectric material. In some embodiments, layer 120 has a lower relative permittivity than layer 110. The greater thickness T₁ of a low-K layer 120 may minimize or at least reduce the relative permittivity (and so the parasitic capacitances) between lines 140, for example, relative to interconnect structures with thinner or higher-permittivity layers 120. Metal lines 140 in both metallization layers 101, 102 have a height H greater than a height or thickness T₂ of dielectric layer 110.

Dielectric angle ϕ₃ is in dielectric layer 120 in or below interconnect layer 101. Dielectric angle ϕ₃ measures at least 90° between metal line 140 (of layer 101) and sidewall 235 of via 130 in or below layer 101. Sidewalls 135, 235 may be the same or different sidewalls. Dielectric angle ϕ₄ is in dielectric layer 120 in or level with interconnect layer 101. Dielectric angle ϕ₄ measures at least 90° between dielectric layer 110 over layer 101 and a sidewall 235 of via 130, in or below interconnect layer 101. Dielectric angle ϕ₄ may also be at least 90° between dielectric layer 110 over layer 101 and sidewall 235 of metal line 140 in interconnect layer 101.

FIGS. 2C, 2D, and 2E illustrate expanded views 200 of some embodiments of reentrant-profile via 130 coupling metal line 140 adjacent dielectric layers 110, 120. View 200 is within the y-z viewing plane shown in FIG. 2B, but similar cross-sections through sidewalls 134, 135 of via 130 may be in other vertical planes. FIG. 2C shows via 130 through dielectric layers 110, 120 with neck 136 at interface 115 between layers 110, 120. Dielectric angle ϕ₁ in dielectric layer 110 measures greater than 90° between sidewall 134 and an upper surface 147 of metal line 140. Much as previously described, e.g., at FIG. 1A, dielectric angle ϕ₂ in dielectric layer 120 measures less than 90° between dielectric layer 110 (e.g., at an interface 115 between layers 110, 120) and sidewall 135. Sidewalls 134, 135 meet or interface at a clean or abrupt corner or edge at neck 136 between sidewalls 134, 135.

FIG. 2D illustrates via 130 through dielectric layers 110, 120 with neck 136 at interface 115 between layers 110, 120. Dielectric angle ϕ₁ in layer 110 measures greater than 90° between sidewall 134 and surface 147. Dielectric angle ϕ₂ in dielectric layer 120 may measure less than 90° between layer 110 and sidewall 135 as previously described. Notably, a rounded-off meeting or interface of sidewalls 134, 135 is at neck 136. In some embodiments, angle ϕ₂ may be measured (e.g., less than) 90° between layer 110 (e.g., at interface 115) and tangent line or ray 201, which extends from a straight length or plane of sidewall 135.

FIG. 2E shows via 130 through dielectric layers 110, 120 with neck 136 at interface 115 between layers 110, 120. Dielectric angle ϕ₁ in layer 110 measures greater than 90° between sidewall 134 and surface 147. Dielectric angle ϕ₂ in dielectric layer 120 may measure less than 90° between layer 110 and sidewall 135 as previously described. Notably, sidewalls 134, 135 meet or interface at a jutting of layers 110, 120 inward towards a vertical axis of via 130. In some embodiments, angle ϕ₂ may be measured (e.g., less than) 90° between layer 110 (e.g., at interface 115) and tangent line or ray 201, which extends from a straight length or plane of sidewall 135. Although the inward jutting of layers 110, 120 (and the consequent narrowing of via 130 at neck 136) is not optimal (e.g., for minimizing local peaks of current density), the peak of current density at neck 136 is comfortably and beneficially removed from the joining or interface between via 130 and metal line 140 (e.g., at surface 147).

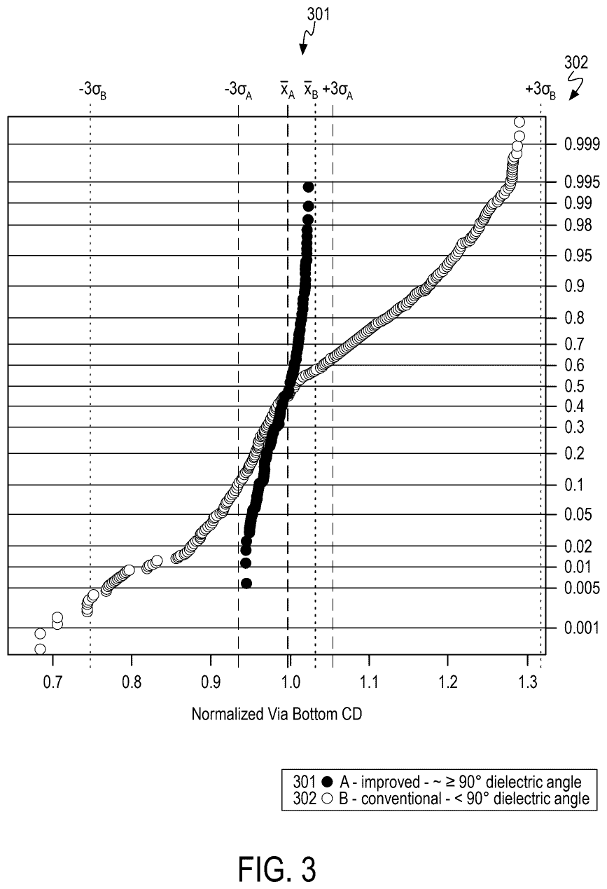

FIG. 3 is a plot of cumulative distribution functions (CDF) corresponding to via bottom widths for both improved and conventional via structures, in accordance with some embodiments. FIG. 3 shows via bottom CDs (e.g., width W₁ in FIG. 1A, etc.) on a normalized x-axis, comparing the improved via structure (data 301) and a conventional via structure (data 302). The y-axis shows the corresponding probability of a measured via bottom width being less than or equal to the plotted normalized via bottom CD.

Data 301 (and associated A-series statistics, e.g., x̅_{A} and +/−3σ_{A}) show that the improved, more-controlled process results in a tight distribution of via bottom CD (e.g., width W₁), for example, with much narrower standard deviations (+/−3σ_{A}). Notably, there are no outliers of low width W₁ away from the data 301, A-series distribution. Electromigration-induced opens at via bottoms are posited to be from outliers below the distribution, i.e., having sub-normal via-bottom contacts or interface widths.

Data 302 (and associated B-series statistics, e.g., x̅_{B} and +/−3σ_{B}) show that the conventional process produces a high-variance distribution of via bottom CD, for example, with much broader standard deviations (+/−3σ_{B}). Notably, there are many outliers of low width W₁, separated and away from the bulk of the non-continuous data 302, B-series distribution. Electromigration-induced opens at via bottoms are likely to be from these outliers having significantly below-normal via-bottom contact widths.

Investigation has shown that the electromigration time-to-fail variance is mostly driven by overly sloped dielectric angles (e.g., angle ϕ₁ in FIG. 1A, etc., away from) ˜90°. These skewed angles in the bottom dielectric layer facilitates the via opening from the bottom contact or interface with the lower metal line. A conventional process has a large variance of via bottom CD correlated with low-width outliers and bottom dielectric layer slope. The improved process better controls the interface angle in the dielectric layer (e.g., at nearly) 90° and avoids low-width outliers.

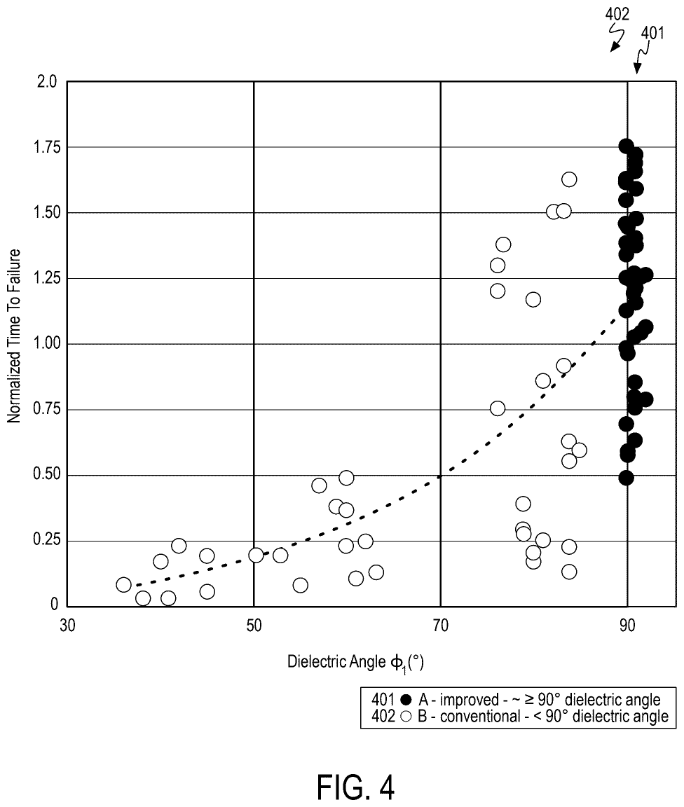

FIG. 4 is a plot of reliability testing time-to-failure results in relation to the dielectric angle at the via bottom, in accordance with some embodiments. As shown in FIG. 4, time to failure, a key electromigration metric in reliability testing, appears related to the dielectric angle at via bottom surface (e.g., in FIG. 1A, etc., angle ϕ₁ in lower dielectric layer 110 at via bottom surface 138) in that early, high-variance, metal-pull electromigration failures are common (perhaps even expected) at low angles ϕ₁. A larger angle ϕ₁ (up to nearly 90° or more) appears to prevent early, copper-pull related, electromigration failures.

Data 401 are those via structures in reliability testing with a dielectric angle at via bottom of approximately 90° or more. Data 402 are those via structures in reliability testing with a dielectric angle at via bottom of about 85° or less. Data 401 show that the improved, more-controlled process results in a nearly continuous distribution of time to failure and an at least relatively reliable minimum time to failure.

Data 402 show a wide variance of times to failure depending somewhat on the dielectric angle at via bottom. At lower angles (e.g., of about 65° or less), all tested samples fail at least as soon as the earliest high-angle failure. At intermediate angles (e.g., between about 75° and) 85°, the tested samples fail unpredictably (i.e., unreliably), with some failing as early as some low-angle failures and others faring as well as some high-angle failures.

For reliable IC devices, a predictable and consistent electromigration time to failure must be demonstrated. The improved via structure (e.g., with a lower dielectric angle of approximately 90° or more), provides a least-variance via bottom CD and a predictable and consistent electromigration time to failure. The improved via structure helps achieve acceptable and predictable reliability performance with minimal via bottom CD variance and without any early failures.

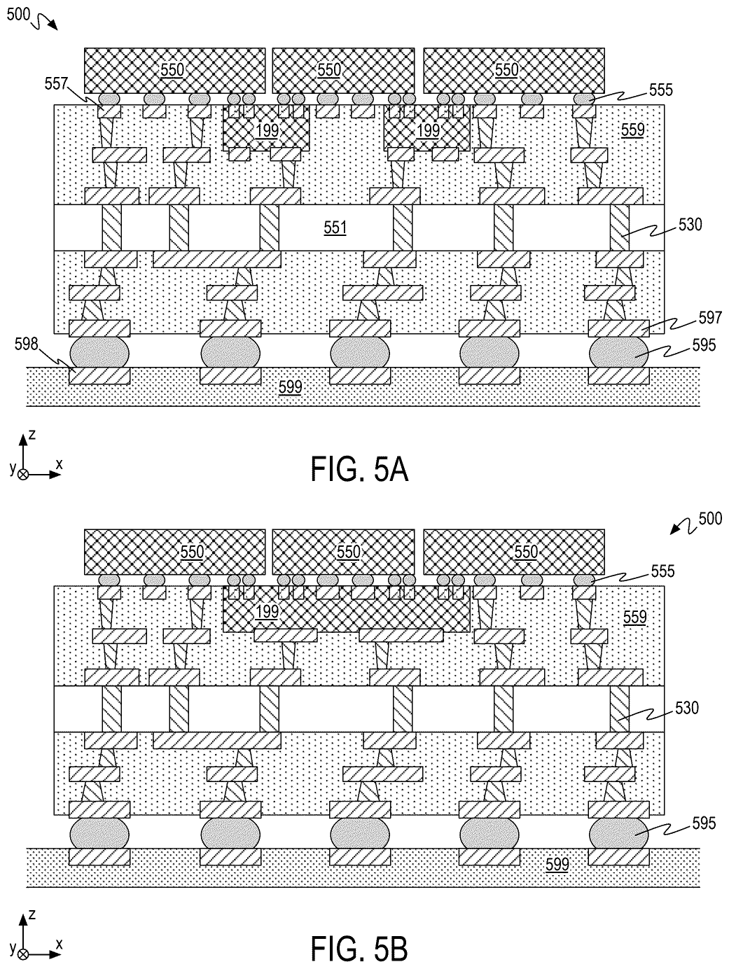

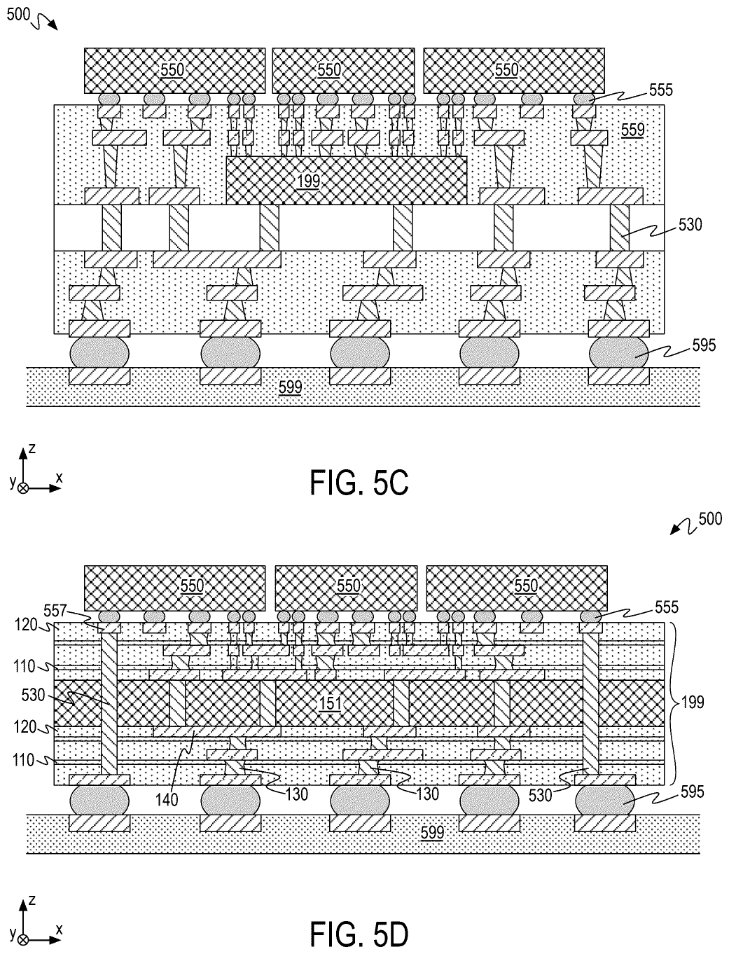

FIGS. 5A, 5B, 5C, and 5D illustrate cross-sectional profile views of IC devices 500 including IC dies 550 coupled by substrate 199, in accordance with some embodiments. FIG. 5A shows IC device 500 including multiple IC dies 550 coupled with each of multiple substrates 199. IC device 500 includes a substrate 559, such as a package substrate 559, coupled to a host component 599. Host component 599 may be any suitable host component 599.

Each of substrates 199 are between multiple IC dies 550 and couple groups (e.g., pairs) of dies 550. First, second, etc., IC dies 550 are coupled by substrate 199. IC dies 550 are coupled to at least other dies 550 by substrate 199. For example, substrates 199 may be bridge dies (for example, of silicon or another crystalline material) with fine-pitched interconnect interfaces direct bonded, e.g., hybrid bonded, to IC dies 550. IC dies 550 may be coupled (for example, electrically) by vias 130 and metal lines 140 (both not shown) in substrates 199, as described at FIG. 1A, etc. The interconnect interfaces of substrates 199 may have a smaller pitch than is feasible with organic substrates. Such pitches and interconnect interfaces may be enabled by fabrication in an IC, e.g., silicon or other semiconductor, back-end-of-line (BEOL) process. In some embodiments, substrate 199 and dies 550 are coupled by solder, e.g., bumps 555. Substrate 199 may be considered on (or part of) substrate 559.

Substrate 559 is a planar platform and may include dielectric and metallization structures. Substrate 559 mechanically supports and electrically couples one or more IC dies 550. At least one side of substrate 559 includes substrate interconnect interfaces 557 for bonding to one or more substrates 199 and/or IC dies 550. IC dies 550 may be direct bonded, e.g., hybrid bonded, to substrate 559 (e.g., at substrates 199) or otherwise bonded, e.g., by optional solder bumps 555. The opposite side of substrate 559 may include similar interfaces 597, e.g., copper pads for socketing and/or solder bumps 595 for bonding device 500 to a host component 599, such as a printed circuit board (PCB). Substrate 559 may be any host component with substrate interconnect interfaces 557, such as a package substrate 559 or interposer, another IC die, etc. Substrate 559 may itself be a die. In many embodiments, substrate 559 includes organic dielectric(s), such as a resin or other polymer, between metallization layers. For example, substrate 559 may include build-up dielectric and metallization layers over and on both sides of a core layer 551. Substrate 559 may include vias 530 through one or more dielectric layers, such as core layer 551, and between one or more metallization layers. Substrate 199 may be on an upper surface of substrate 559.

Substrate 559 may couple with any host component 599. Host component 599 is a planar platform, such as a substrate, and may include dielectric and metallization structures. Host component 599 may mechanically support, and electrically couple to, substrate 559. At least one side of host component 599 includes interconnect interfaces 598, e.g., for soldering or otherwise coupling to substrate 559. In many embodiments, host component 599 is a PCB (such as a mother board), and substrate 559 is a package substrate 559. In some embodiments, substrate 199 is coupled to one or more IC dies 550 each having one or more transistor structures (not shown), and the transistor structure(s) are coupled to a power supply (not shown) through substrate 199 (and one or more vias 130, as described at FIG. 1A, etc., in substrate 199), substrate 559, and host component 599.

FIG. 5B illustrates IC device 500, for example, similar to device 500 of FIG. 5A, including multiple IC dies 550 coupled with a large substrate 199 spanning beyond the edges of a central IC die 550. Substrate 199 may be a bridge or interposer die, e.g., providing power and signal routing between IC dies 550. Substrate 199 may be direct (e.g., hybrid) bonded, or otherwise coupled, with IC dies 550.

FIG. 5C shows a similar substrate 199 as in device 500 of FIG. 5B, e.g., a large bridge or interposer die, but embedded in substrate 559. Substrate 199 may be in or between dielectric and metallization layers of substrate 559 and coupled with IC dies 550 by vias 530. In many embodiments, IC dies 550 are coupled with substrates 199, 559 by solder bumps 555.

FIG. 5D illustrates IC device 500 with a large substrate 199 coupled to, and between, host component 599 and multiple IC dies 550. Substrate 199 may provide power and signal routing between IC dies 550 and to dies 550 from host component 599 (and a power supply, etc., not shown, through host component 599). IC dies 550 may be direct (e.g., hybrid) bonded, or otherwise coupled (e.g., by bumps 555), with substrate 199, which may have fine-pitched interconnect interfaces 557.

Substrate 199 may include vias 130 (as previously described, e.g., with a neck between reentrant sidewalls tapering from wider ends) coupled to metal lines 140. Lines 140 extend laterally through dielectric layers 120 (e.g., in interconnect layers, such as layers 101, 102 of FIG. 1A, etc.), and vias 130 extend vertically between lines 140 and through dielectric layers 110, 120. Dielectric layers 110, 120 may be over and on both sides of a core layer 151 of substrate 199, for example, a layer 151 of semiconductor or other crystalline material. Layers 110, 120 may be build-up layers on a front- and back-side of core layer 151.

Substrate 199 may include through vias 530 (e.g., through-silicon vias, TSV 530) that couple one or more IC dies 550. Through vias 530 may directly couple dies 550 with host component 599, for example, to provide power and/or ground paths directly to at least some dies 550. In some embodiments, substrate 199 includes transistor structures. In other embodiments, IC dies 550 includes transistor structures, and vias 130 in substrate 199 couple transistor structures in dies 550 to a power supply (not shown) through host component 599. In some embodiments, IC dies 550 includes transistor structures, and through via(s) 530 in and through substrate 199 couple(s) transistor structures in dies 550 to a power supply (not shown) through host component 599.

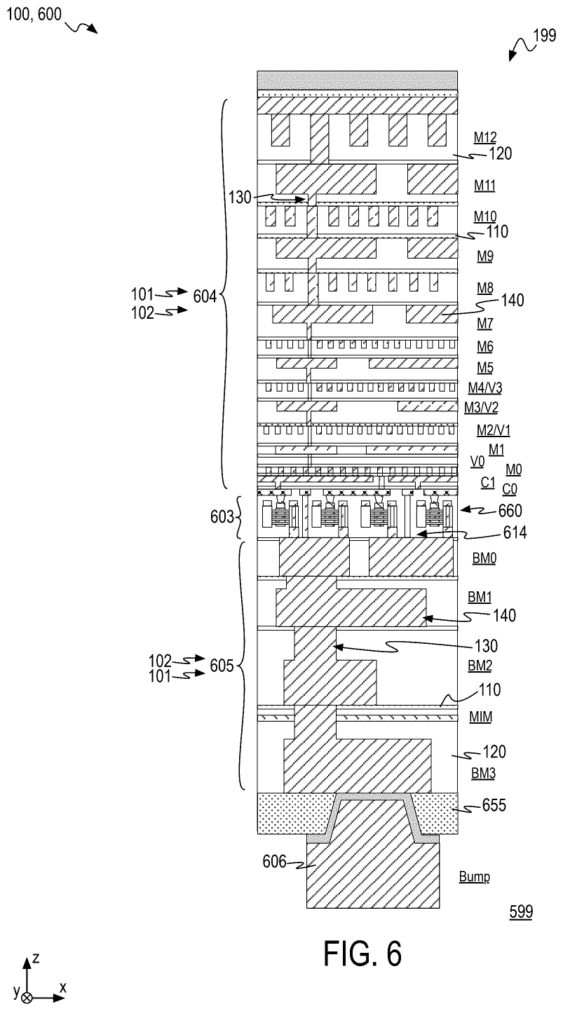

FIG. 6 illustrates a cross-sectional view of an IC system 600 having improved vias 130 in front- and back-side interconnect sections 604, 605, over and under transistor structures 660 in a device layer 603, in accordance with some embodiments. In the example of IC system 600, substrate 199 is an IC die having improved vias 130 in front- and back-side interconnect sections 604, 605. IC system 600 includes a lateral surface along the x-y plane that may be defined or taken at any vertical position of IC system 600. The lateral surface of the x-y plane is orthogonal to a vertical or build-up dimension as defined by the z-axis. In some embodiments, IC system 600 may be formed from any substrate material suitable for the fabrication of transistor circuitry. In some embodiments, a semiconductor substrate is used to manufacture transistor structures 660 and other transistors and components of IC system 600. The semiconductor substrate may include a wafer or other piece of silicon or another semiconductor material. Suitable semiconductor substrates include, but are not limited to, single crystal silicon, polycrystalline silicon and SOI, as well as similar substrates formed of other semiconductor materials, such as gallium arsenide. The substrate may also include semiconductor materials, metals, dielectrics, dopants, and other materials commonly found in semiconductor substrates.

In FIG. 6, IC system 600 includes an IC substrate 199, which is a monolithic IC as described above, including transistor structures 660 in device layer 603, front-side interconnect or metallization layers 101, 102 in section 604, and optional back-side interconnect or metallization layers 101, 102 in section 605. As shown, transistor structures 660 are non-planar transistors within device layer 603 between interconnect sections 604, 605. Each of transistor structures 660 include channel regions (e.g., within nanoribbons or nanosheets), gate structures, and gate contacts, as well as source and drain structures, and source and drain contacts. In some embodiments, front-side metallization section 604 provides signal routing to transistor structures 660 and back-side metallization section 605 provide power delivery, as enabled by through-contacts 614 to transistor structures 660. IC system 600 may also be deployed without back-side metallization section 605 shown in FIG. 6. In such embodiments, signal routing and power are provided to transistor structures 660 via front-side metallization section 604. However, use of back-side metallization section 605 may offer advantages.

Interconnectivity of transistor structures 660 (and other transistors, etc.), including signal routing, power delivery, etc., and routing to an outside device (not shown), is provided by front-side metallization section 604, back-side metallization section 605, and package-level interconnects 606. In the example of FIG. 6, package-level interconnects 606 are provided on or over a back-side of IC substrate 199 as bumps over a passivation layer 655, and IC system 600 is attached to host component 599 (and coupled to signal routing to, power delivery, etc.) by package-level interconnects 606. However, package-level interconnects 606 may be provided (and substrate 199 and transistor structures 660 may be coupled to host component 599) using any suitable interconnect structures such as bond pads, solder bumps, etc. Likewise, substrate 199 and transistor structures 660 may be coupled to any suitable power supply (not shown) through host component 599. Furthermore, in some embodiments, package-level interconnects 606 are provided on or over a front-side of IC substrate 199 (i.e., over front-side metallization section 604) rather than on or over a back-side of IC substrate 199.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, including metallization lines 140, are interconnected by vias, such as vias 130, that may be characterized as part of metallization layers 101, 102 or between metallization layers 101, 102. As shown, in some embodiments, front-side metallization section 604 is formed over and immediately adjacent transistor structures 660. The back-side is then the opposite side, which may be exposed during processing by attaching the front-side to a carrier wafer and exposing the back-side (e.g., by back-side grind or etch operations) as known in the art.

In the illustrated example, front-side metallization section 604 includes metallization lines and vias in layers M0, V0, M1, M2/V1, M3/V2, M4/V3, and M4-M12. However, front-side metallization section 604 may include any number of metallization layers such as eight or more metallization layers. Similarly, back-side metallization section 605 includes BM0, BM1, BM2, and BM3. However, back-side metallization section 605 may include any number of metallization layers such as two to five metallization layers. Metallization lines 140 are embedded within dielectric layers 120 in front- and back-side metallization sections 604, 605. Vias 130 extend through dielectric layers 110, 120 in front- and back-side sections 604, 605. Furthermore, optional metal-insulator-metal (MIM) devices such as diode devices may be provided within back-side metallization section 605. Other devices such as capacitive memory devices may be provided within front-side metallization section 604 and/or back-side metallization section 605.

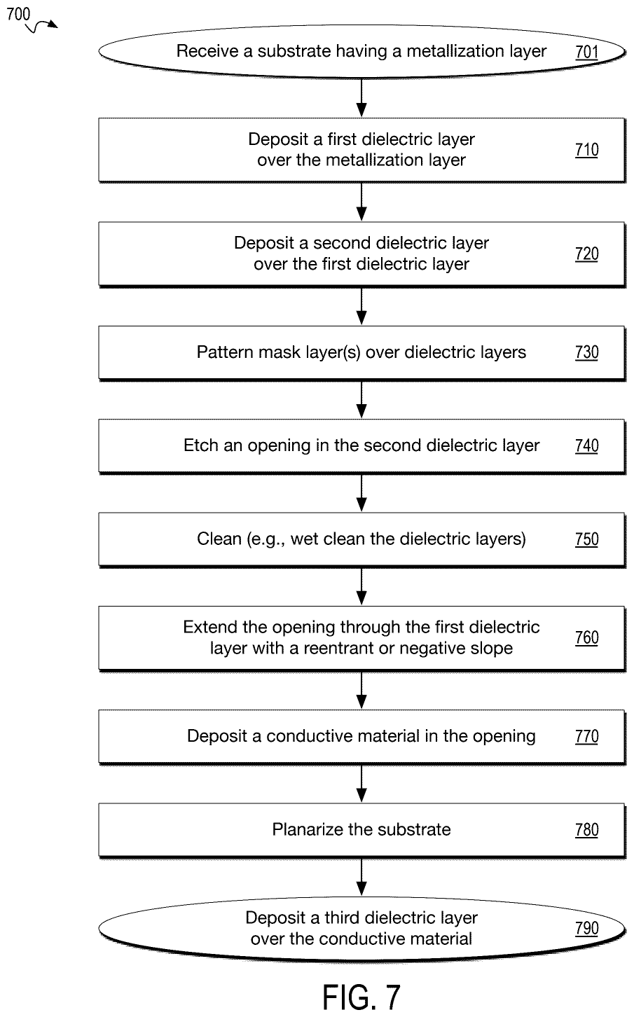

FIG. 7 is a flow chart of methods 700 for forming a conductive via with a reentrant bottom sidewall in one or more dielectric layers, in accordance with some embodiments. Methods 700 include operations 701-790. Some operations shown in FIG. 7 are optional. Additional operations may be included. FIG. 7 shows an example sequence, but the operations can be done in other orders as well, and some operations may be omitted. Some operations can also be performed multiple times before other operations are performed. For example, multiple via openings may be formed, e.g., concurrently, in an upper dielectric layer. Some operations may be included within other operations so that the number of operations illustrated FIG. 7 is not a limitation of the methods 700.

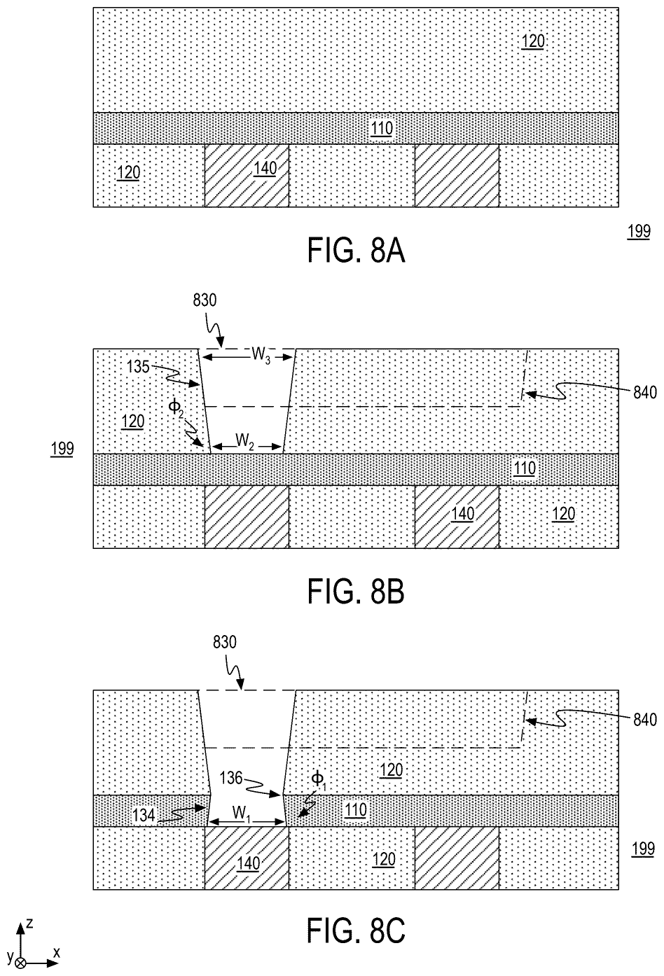

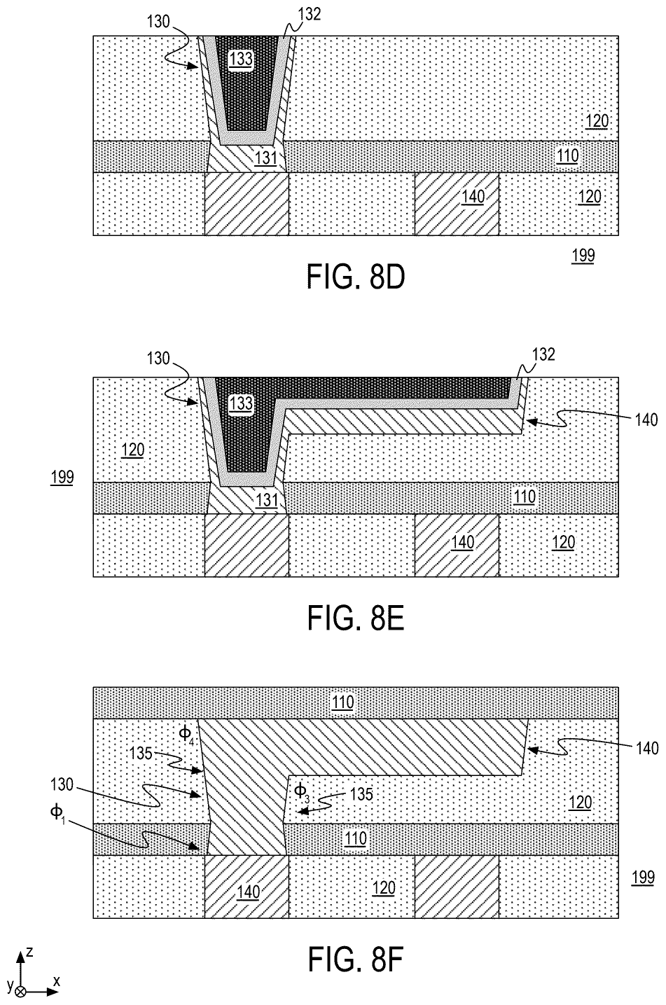

FIGS. 8A, 8B, 8C, 8D, 8E, and 8F illustrate cross-sectional profile views of a device having a conductive via with a reentrant bottom sidewall, at various stages of manufacture, in accordance with some embodiments. FIGS. 8A-8F show possible examples of intermediate structures during an embodiment of a practice of methods 700 of FIG. 7.

Returning to FIG. 7, methods 700 begin at operation 701 by receiving a substrate. The substrate may be much as previously described, e.g., at FIG. 1A. For example, the substrate may be a wafer or die of a semiconductor or other crystalline material. Such a substrate may provide mechanical support for the deposition of other layers, e.g., of dielectric and conductive materials. In some embodiments, the substrate includes an interconnect or metallization layer. Such a layer may include one or more conductive lines in a dielectric layer. For example, the lines may be bars or wires of an electrically conductive metal in trenches of an electrically insulating material. Such an electrically insulating material may advantageously be a low-K dielectric material.

Methods 700 continue with depositing a dielectric layer over the metallization layer at operation 710. The dielectric layer may be a cap or etch-stop layer over the layer below. For example, the dielectric layer may be of a different dielectric material than that of the interconnect or metallization layer. A cap or etch-stop dielectric material may have an etch selectivity with the existing, previous dielectric material. For example, the interconnect layer below may have metal lines embedded in a low-K oxide (e.g., of silicon), and the newly deposited (e.g., cap or etch-stop) dielectric layer may be a nitride or carbide layer. A cap or etch-stop dielectric layer need not be overly thick. In some embodiments, a dielectric layer of silicon and either (or both of) nitrogen or carbon is deposited over the metallization layer. In some such embodiments, a dielectric layer of silicon, nitrogen, and carbon is deposited over the metallization layer. For example, a thin layer (e.g., with a thickness of less than 200 nm) of silicon and carbon is deposited doped with nitrogen, and the thin layer covers the interconnect layer.

Methods 700 continue at operation 720 by depositing a dielectric layer over the lower dielectric layer (which is over the metallization layer). In some embodiments, this upper dielectric layer over the lower dielectric layer (e.g., a cap layer) is deposited more thickly and with a lower relative permittivity than the lower layer. This thicker, lower-K layer may mechanically support and electrically isolate metal (or other conductive) lines through the dielectric layer. In some embodiments, a thicker (e.g., >200 nm) layer is formed by depositing silicon and oxygen (e.g., in an oxide of silicon) by any suitable means.

FIG. 8A illustrates a cap or etch-stop layer 110 over metal lines 140 in a lower, low-K dielectric layer 120, and an upper, low-K dielectric layer 120 over layer 110, in accordance with some embodiments, for example, following a performance of a depositing operation 720. The layers 110, 120 are in or on substrate 199, as described.

Returning to FIG. 7, methods 700 continue by patterning one or more mask layers over the dielectric layers at operation 730. Any suitable means may be used. In many embodiments, one or more photolithographic layers (e.g., including a multi-part photoresist layer, a bottom anti-reflective coating (BARC), etc.) are employed to form desired patterns in a mask layer over the dielectric layers. For example, a hardened mask layer may be formed with an opening patterned in the mask where a via is to be formed. Pre-corrections may be made to the pattern to ensure properly sized and shaped openings will be etched in the dielectric layer(s).

Methods 700 continue at operation 740 by etching an opening in the upper (e.g., thicker, lower-K) dielectric layer. Any suitable means may be used to open up a void in the dielectric. In many embodiments, a dry, anisotropic etch forms a substantially vertical opening down through the mask layer and into the upper dielectric layer. In many embodiments, the etch of the upper dielectric layer is at least somewhat selective to the cap dielectric layer, and the etch stops at the cap dielectric layer over the metallization layer. In many embodiments, the etched opening has at least a slight taper with a width at a top of the opening greater than a width at a bottom of the opening (at the cap dielectric layer over the metallization layer). A sidewall angle in the upper dielectric layer may be less than 90°.

In some embodiments, the etching the opening through the upper dielectric layer includes forming (e.g., opening, etching) a trench in the upper dielectric layer. In some such embodiments, the opening (e.g., for the via) extends downward, toward the cap or etch-stop dielectric layer from the trench. Subsequent deposition of conductive material may then be in the trench portion of the opening to form a metal line, e.g., concurrently with or after deposition of conductive material in the via portion of the opening (e.g., below the trench). Such deposition will ensure an upper metal line and metallization layer is coupled to the lower metal line and metallization layer by the via.

FIG. 8B illustrates opening 830 in and extending through dielectric layer 120, down to dielectric layer 110, in accordance with some embodiments, for example, following a performance of an etching operation 740. Etched opening 830 has a taper with width W₃ at a top of opening 830 greater than width W₂ at a bottom of opening 830 (at the cap dielectric layer 110 over metallization line 140). Sidewall angle ϕ₂ in upper dielectric layer 120 is less than 90°.

In some embodiments, a trench opening 840 is continuous with opening 830 in layer 120, e.g., at a top of opening 830, with a portion of layer 120 above layer 110, between opening 840 and layer 110. Opening 840 may be filled to form a metal line 140 through layer 120.

Returning to FIG. 7, methods 700 continue with cleaning the dielectric layers at operation 750. Cleaning may improve subsequent electrical performance by removing any residue(s) after plasma etch, e.g., before metal(s) deposition. In some embodiments, oxygen ashing may be used. In some embodiments, a wet clean is used alternatively or additionally. For example, one or more chemical cleans may be utilized on the exposed dielectric material, including the via and trench openings. Such chemicals may include ammonia, hydrogen peroxide, hydrochloric acid, fluoride-based cleaner(s), etc. Any suitable clean may be employed.

Methods 700 continue by extending the opening through the lower dielectric layer with a reentrant or negative slope at operation 760. In many embodiments, the opening is extended with another etch. In many embodiments, a dry, anisotropic etch extends the opening down into and through the lower dielectric layer. In many embodiments, the etch of the lower dielectric layer is at least somewhat selective to the metallization layer, removing material of the lower dielectric layer and stopping at, and retaining, the metallization layer. An etch selective to the metallization layer prevents an undercut of the metallization layer under the lower dielectric layer. Etching under the lower dielectric layer may form voids that subsequent deposition (e.g., of a metal liner layer) will not fill in. Such voids may then act as a notch for crack initiation and propagation and lead to early failures, e.g., during reliability testing or in the field. In many embodiments, the opening has a width at a neck at an interface between the upper and lower dielectric layers, and the extending the opening into and through the lower dielectric layer etches the opening in the lower dielectric layer to a wider width greater than the width at the neck. In many embodiments, the extending the opening into and through the lower dielectric layer forms an angle in the lower dielectric layer measuring greater than 90° between the metal line of the metallization layer and a sidewall of the lower dielectric layer.

FIG. 8C illustrates an extended opening 830 down into and through dielectric layer 110, in accordance with some embodiments, for example, following a performance of etching operation 760. Opening 830 has a width W₁ at a bottom of opening 830 greater than width W₂ now at neck 136 of opening 830. Angle ϕ₁ in lower dielectric layer 110 measures greater than 90° between metal line 140 and sidewall 134 of lower dielectric layer 110.

Returning to FIG. 7, methods 700 continue at operation 770 by depositing a conductive material in the opening. The conductive material may be deposited by any suitable means, e.g., a physical vapor deposition (PVD) or chemical vapor deposition (CVD). In many embodiments, the conductive material is a metal. In some embodiments, multiple metals are deposited in the opening. For example, a barrier and/or seed layer of metal may be conformally deposited before a bulk metal fills the space lined by the conformal layer(s). In many embodiments, the deposited conductive material forms a via in the opening through the dielectric layers. In some embodiments, the deposited conductive material forms a line extending through the upper dielectric layer. The line in the upper dielectric layer is a second line in a second metallization layer over the first line and layer. In many embodiments forming a line in the upper dielectric layer, depositing the conductive material in the opening forms an upper metal line and layer through in and through the upper dielectric layer and forms a via coupled to the upper metal line (e.g., sharing conformal metal layer(s) and metal fill) and the lower metal line (e.g., under the lower dielectric layer, at a bottom of the now-filled opening).

In many embodiments, forming the upper metal line and metallization layer forms a metal line with an angle measuring at least 90° between the metal line and a sidewall of the upper (e.g., low-K) dielectric layer.

In many embodiments, forming the upper metal line and metallization layer couples first and second transistor structures below the upper metallization layer, and the first and second transistor structures are coupled by the metal line and the via formed by the deposition of the conductive material. For example, the formed upper metal line may be coupled to a separate via at each end of the metal line.

Methods 700 continue with planarizing the substrate at operation 780. In many embodiments, the deposited conductive material (e.g., metal) is deposited up to and over an upper surface of the (low-K) dielectric layer. In some such embodiments, excess metal (etc.) over the upper surface is planarized, e.g., removed by chemical-mechanical polishing (CMP) or planarizing.

FIG. 8D illustrates via 130 with reentrant, lower sidewall 134 extending through dielectric layers 110, 120 and coupling metal line 140, in accordance with some embodiments, for example, following a performance of depositing operation 770 and planarizing operation 780. Via 130 includes barrier layer 131 on metal line 140, seed layer 132 on barrier layer 131, and bulk fill portion 133 in and on layer 132. FIG. 8D shows an embodiment without a line 140 shown in upper dielectric layer 120, at least not in the x-z cross-section of FIG. 8D.

FIG. 8E illustrates a similar via 130 extending through dielectric layers 110, 120 and coupling lower and upper metal lines 140, in accordance with some embodiments, for example, following a performance of depositing operation 770 and planarizing operation 780. In the embodiment of FIG. 8E, upper metal line 140 and via 130 are portions of an integrated structure and share conductive layers 131, 132 and portion 133.

Returning to FIG. 7, methods 700 continue by depositing another cap dielectric layer over the conductive material (e.g., metal line(s) in the metallization layer) at operation 790. Such a deposition may be part of a new iteration of forming a via and/or metal line in a new interconnect or metallization layer.

FIG. 8F illustrates an upper cap dielectric layer 110 over via 130 extending through dielectric layers 110, 120 and coupling metal lines 140 in separate metallization layers, in accordance with some embodiments, for example, following a performance of depositing operation 790. Angle ϕ₃ between sidewall 135 and upper metal line 140 and metallization layer measures at least 90° between line 140 and sidewall 135 of the upper dielectric layer 120. Angle ϕ₄ between sidewall 135 and upper cap layer 110 measures at least 90°.

In some embodiments, the substrate is coupled to an IC die, which couples a transistor structure to a power supply through the via. For example, a transistor structure in the coupled IC die may be coupled to a mother board through the substrate, which may be a bridge or interposer die.

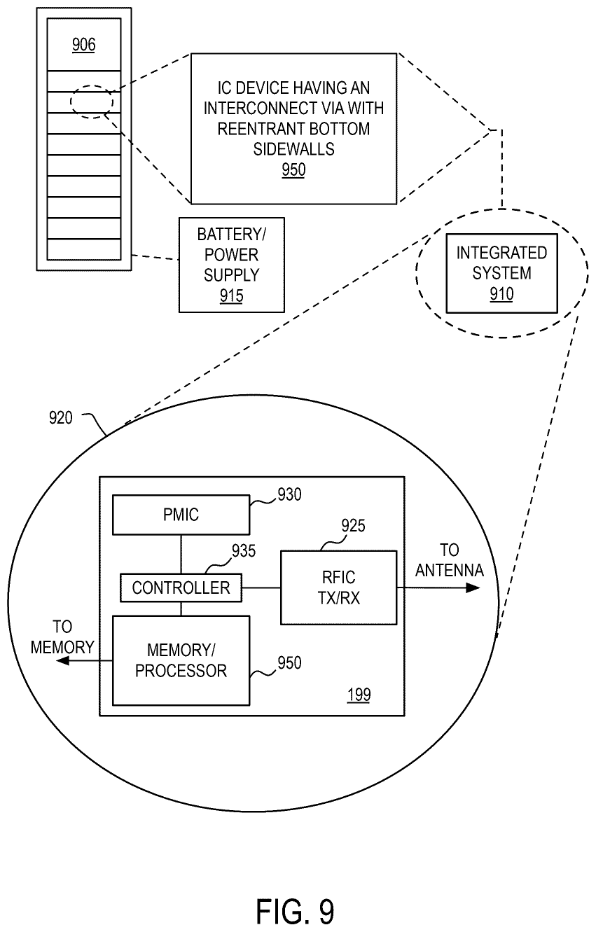

FIG. 9 illustrates a diagram of an example data server machine 906 employing an IC device having an interconnect via with reentrant bottom sidewalls, in accordance with some embodiments. Server machine 906 may be any commercial server, for example, including any number of high-performance computing platforms disposed within a rack and networked together for electronic data processing, which in the exemplary embodiment includes one or more devices 950 with an interconnect via having reentrant bottom sidewalls.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 950 is a microprocessor including a static RAM (SRAM) cache memory. As shown, device 950 may be an IC device having an interconnect via with reentrant bottom sidewalls, as discussed herein. Device 950 may be further coupled to (e.g., communicatively coupled to) a board, an interposer, or a substrate 199 along with, one or more of a power management IC (PMIC) 930, RF (wireless) IC (RFIC) 925 including a wideband RF (wireless) transmitter and/or receiver (TX/RX) (e.g., including a digital baseband and an analog front end module further includes a power amplifier on a transmit path and a low noise amplifier on a receive path), and a controller 935 thereof. In some embodiments, one or more of RFIC 925, PMIC 930, controller 935, and device 950 are IC substrates 199 including an interconnect via 130 having reentrant bottom sidewalls (e.g., as described at FIG. 1A, etc.). In some such embodiments, RFIC 925, PMIC 930, controller 935, and/or device 950 are coupled by a host component 599 (e.g., as described at FIGS. 5A-6).

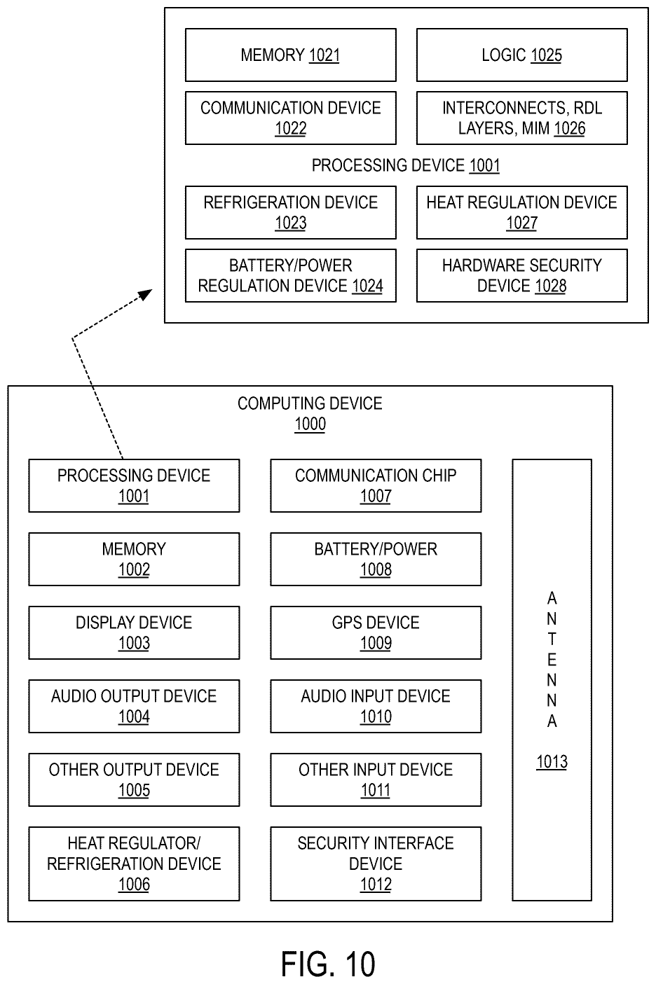

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-MRAM).

Computing device 1000 may include a heat regulation/refrigeration device 1006. Heat regulation/refrigeration device 1006 may maintain processing device 1001 (and/or other components of computing device 1000) at a predetermined low temperature during operation.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16 2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a metallization layer on a substrate, a first dielectric layer over the metallization layer, a second dielectric layer over the first dielectric layer, wherein the second dielectric layer has a first thickness greater than a second thickness of the first dielectric layer, and a via coupled with the metallization layer, wherein the via includes a metallic material, the via extends through the first and second dielectric layers, and an angle in the first dielectric layer measures greater than 90° between the metallization layer and a sidewall of the via.

In one or more second embodiments, further to the first embodiments, the via has a first width at a first interface between the via and the metallization layer, a second width at a second interface between the first and second dielectric layers, the first width greater than the second width, and a third width above the second interface, the third width greater than the second width.

In one or more third embodiments, further to the first or second embodiments, the angle is a first angle, the sidewall is a first sidewall, and a second angle in the second dielectric layer measures less than 90° between the first dielectric layer and a second sidewall of the via.

In one or more fourth embodiments, further to the first through third embodiments, the second angle is within 4° of the first angle.

In one or more fifth embodiments, further to the first through fourth embodiments, the metallization layer is a first metallization layer, the angle is a first angle, the sidewall is a first sidewall, a second metallization layer is coupled to the first metallization layer by the via, the second dielectric layer between the first and second metallization layers, and a third angle in the second dielectric layer measures at least 90° between the second metallization layer and the first or a second sidewall of the via.

In one or more sixth embodiments, further to the first through fifth embodiments, the metallization layer is a first metallization layer, the angle is a first angle, the sidewall is a first sidewall, a second metallization layer is coupled to the first metallization layer by the via, the second dielectric layer between the first and second metallization layers, and a fourth angle in the second dielectric layer measures at least 90° between a third dielectric layer over the second metallization layer and the first or a second sidewall of the via.

In one or more seventh embodiments, further to the first through sixth embodiments, the first and third dielectric layers include silicon, carbon, and nitrogen, and the second dielectric layer includes silicon and oxygen.

In one or more eighth embodiments, further to the first through seventh embodiments, first and second IC dies are coupled by the substrate.

In one or more ninth embodiments, further to the first through eighth embodiments, the via is a first via, the substrate is coupled to an IC die, the substrate includes a second via, the second via extends through the substrate, and the second via is coupled to the IC die.

In one or more tenth embodiments, further to the first through ninth embodiments, the substrate includes a transistor structure, and the metallization layer and the first and second dielectric layers are over or under the transistor structure.

In one or more eleventh embodiments, further to the first through tenth embodiments, the substrate is a first substrate, the first substrate is coupled to a second substrate, and the transistor structure is coupled to a power supply through the second substrate.

In one or more twelfth embodiments, an apparatus includes first and second metallization layers on a substrate, a dielectric layer between the first and second metallization layers, and a via between and coupled with the first and second metallization layers, wherein the via includes a metallic material, the via extends through the dielectric layer, a first dielectric angle in the dielectric layer measures greater than 90° between the first metallization layer and a sidewall of the via, and a second dielectric angle measures at least 90° between the second metallization layer and the first or a second sidewall of the via.

In one or more thirteenth embodiments, further to the twelfth embodiments, the dielectric layer is a first dielectric layer, the second dielectric angle is in a second dielectric layer over the second metallization layer and between the first dielectric layer and the second metallization layer, and the first dielectric layer has a first thickness greater than a second thickness of the second dielectric layer.

In one or more fourteenth embodiments, further to the twelfth or thirteenth embodiments, the via has a first width at a first interface between the via and the second metallization layer, a second width at a second interface between the first and second dielectric layers, the first width greater than the second width, and a third width above the second interface, the third width greater than the second width.

In one or more fifteenth embodiments, further to the twelfth through fourteenth embodiments, a third dielectric angle is in the first dielectric layer and measured from the first, the second, or a third sidewall of the via to the second interface between the first and second dielectric layers, and the second dielectric angle is at least 4° greater than the third dielectric angle.

In one or more sixteenth embodiments, further to the twelfth through fifteenth embodiments, the substrate is coupled to an IC die, the IC die includes a transistor structure, and the transistor structure is coupled to a power supply through the via.

In one or more seventeenth embodiments, a method includes etching an opening through a first dielectric layer on a substrate, wherein the first dielectric layer is over a second dielectric layer, and the second dielectric layer is over a metallization layer, extending the opening into and through the second dielectric layer, wherein an angle in the second dielectric layer measures greater than 90° between the metallization layer and a sidewall of the second dielectric layer, and depositing a conductive material in the opening.

In one or more eighteenth embodiments, further to the seventeenth embodiments, the opening has a first width at an interface between the first and second dielectric layers, and the extending the opening into and through the second dielectric layer includes etching the opening in the second dielectric layer to a second width greater than the first width.

In one or more nineteenth embodiments, further to the seventeenth or eighteenth embodiments, the angle in the second dielectric layer is a first angle, the sidewall of the second dielectric layer is a first sidewall, and the etching the opening through the first dielectric layer forms a second sidewall with a second angle in the first dielectric layer, the second angle measuring at least 90° between the second sidewall and an upper surface of the first dielectric layer.

In one or more twentieth embodiments, further to the seventeenth through nineteenth embodiments, also including depositing the second dielectric layer over the metallization layer, the second dielectric layer including silicon, carbon, and nitrogen, and depositing the first dielectric layer over the second dielectric layer, the first dielectric layer including silicon and oxygen.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a metallization layer on a substrate;
a first dielectric layer over the metallization layer;
a second dielectric layer over the first dielectric layer, wherein the second dielectric layer has a first thickness greater than a second thickness of the first dielectric layer; and
a via coupled with the metallization layer, wherein the via comprises a metallic material, the via extends through the first and second dielectric layers, and an angle in the first dielectric layer measures greater than 90° between the metallization layer and a sidewall of the via.

2. The apparatus of claim 1, wherein the via has:
a first width at a first interface between the via and the metallization layer;
a second width at a second interface between the first and second dielectric layers, the first width greater than the second width; and
a third width above the second interface, the third width greater than the second width.

3. The apparatus of claim 1, wherein the angle is a first angle, the sidewall is a first sidewall, and a second angle in the second dielectric layer measures less than 90° between the first dielectric layer and a second sidewall of the via.

4. The apparatus of claim 3, wherein the second angle is within 4° of the first angle.

5. The apparatus of claim 1, wherein:
the metallization layer is a first metallization layer;
the angle is a first angle;
the sidewall is a first sidewall;
a second metallization layer is coupled to the first metallization layer by the via, the second dielectric layer between the first and second metallization layers; and
a third angle in the second dielectric layer measures at least 90° between the second metallization layer and the first or a second sidewall of the via.

6. The apparatus of claim 1, wherein:
the metallization layer is a first metallization layer;
the angle is a first angle;
the sidewall is a first sidewall;
a second metallization layer is coupled to the first metallization layer by the via, the second dielectric layer between the first and second metallization layers; and
a fourth angle in the second dielectric layer measures at least 90° between a third dielectric layer over the second metallization layer and the first or a second sidewall of the via.

7. The apparatus of claim 6, wherein:
the first and third dielectric layers comprise silicon, carbon, and nitrogen; and
the second dielectric layer comprises silicon and oxygen.

8. The apparatus of claim 1, wherein first and second integrated circuit (IC) dies are coupled by the substrate.

9. The apparatus of claim 1, wherein:
the via is a first via;
the substrate is coupled to an IC die;
the substrate comprises a second via;
the second via extends through the substrate; and
the second via is coupled to the IC die.

10. The apparatus of claim 1, wherein the substrate comprises a transistor structure, and the metallization layer and the first and second dielectric layers are over or under the transistor structure.

11. The apparatus of claim 10, wherein:
the substrate is a first substrate;
the first substrate is coupled to a second substrate; and
the transistor structure is coupled to a power supply through the second substrate.

12. An apparatus, comprising:
first and second metallization layers on a substrate;
a dielectric layer between the first and second metallization layers; and
a via between and coupled with the first and second metallization layers, wherein:
the via comprises a metallic material;
the via extends through the dielectric layer;
a first dielectric angle in the dielectric layer measures greater than 90° between the first metallization layer and a sidewall of the via; and
a second dielectric angle measures at least 90° between the second metallization layer and the first or a second sidewall of the via.

13. The apparatus of claim 12, wherein:
the dielectric layer is a first dielectric layer;
the second dielectric angle is in a second dielectric layer over the second metallization layer and between the first dielectric layer and the second metallization layer; and
the first dielectric layer has a first thickness greater than a second thickness of the second dielectric layer.

14. The apparatus of claim 13, wherein the via has:
a first width at a first interface between the via and the second metallization layer;
a second width at a second interface between the first and second dielectric layers, the first width greater than the second width; and
a third width above the second interface, the third width greater than the second width.

15. The apparatus of claim 14, wherein:
a third dielectric angle is in the first dielectric layer and measured from the first, the second, or a third sidewall of the via to the second interface between the first and second dielectric layers; and
the second dielectric angle is at least 4° greater than the third dielectric angle.

16. The apparatus of claim 15, wherein:
the substrate is coupled to an integrated circuit (IC) die;
the IC die comprises a transistor structure; and
the transistor structure is coupled to a power supply through the via.

17. A method, comprising:
etching an opening through a first dielectric layer on a substrate, wherein the first dielectric layer is over a second dielectric layer, and the second dielectric layer is over a metallization layer;
extending the opening into and through the second dielectric layer, wherein an angle in the second dielectric layer measures greater than 90° between the metallization layer and a sidewall of the second dielectric layer; and
depositing a conductive material in the opening.

18. The method of claim 17, wherein the opening has a first width at an interface between the first and second dielectric layers, and the extending the opening into and through the second dielectric layer comprises etching the opening in the second dielectric layer to a second width greater than the first width.

19. The method of claim 17, wherein the angle in the second dielectric layer is a first angle, the sidewall of the second dielectric layer is a first sidewall, and the etching the opening through the first dielectric layer forms a second sidewall with a second angle in the first dielectric layer, the second angle measuring at least 90° between the second sidewall and an upper surface of the first dielectric layer.

20. The method of claim 17, further comprising:
depositing the second dielectric layer over the metallization layer, the second dielectric layer comprising silicon, carbon, and nitrogen; and
depositing the first dielectric layer over the second dielectric layer, the first dielectric layer comprising silicon and oxygen.
